(19) United States
(12) Patent Application Publication
(10) Pub. No.: US 2012/0126663 A1
(43) Pub. Date: May 24, 2012

(54) METHOD FOR PRODUCING AN ELECTROMECHANICAL CONVERTER

(75) Inventors: Werner Jenninger, Koln (DE); Joachim Wagner, Koln (DE); Carsten Benecke, Weil am Rhein (DE); Thomas Bernert, Oberbillig (DE)

(73) Assignee: BAYER MATERIALSCIENCE AG, LEVERKUSEN (DE)

(21) Appl. No.: 13/388,846

(22) PCT Filed: Jul. 28, 2010
(86) PCT No.: PCT/EP2010/004614

§ 371 Date: Feb. 3, 2012

(30) Foreign Application Priority Data
Aug. 7, 2009 (EP) 09010202.1

(51) Int. Cl. H01L 41/04; H01L 41/26

(52) U.S. Cl. 310/311; 29/25.35

(57) ABSTRACT

The present invention relates to a method for producing an electromechanical, for example piezoelectric, transducer, comprising the steps of: A) applying a monolayer of spacer elements (3) onto a first polymer layer (1), the spacer elements (3) having essentially the same height (h), B) applying a second polymer layer (2) onto the spacer elements (3) of the monolayer so that there is at least one cavity (4) between the first polymer layer (1) and the second polymer layer (2), and C) fixing the spacer elements (3) between the first (1) and second (2) polymer layers.

The present invention relates to a method for producing an electromechanical, for example piezoelectric, transducer, to an electromechanical transducer and to the use of electromechanical transducers.

The ability of materials to generate an electrical potential in response to an exerted mechanical load is referred to as piezoelectricity. Established piezoelectric materials are lead zirconate titanate (PZT) and fluorinated polymers such as polyvinylidene chloride (PVDF). Piezoelectric behaviour has also been observed in closed-pore foamed polypropylene (PP). In order to achieve piezoelectricity, such a polypropylene foam is charged in a strong electric field. Electrical breakdowns consequently take place inside the pores, which generate macrodipoles and macroscopically polarise the material. Such polypropylene ferroelectrets can have a piezoelectric coefficient of a few hundred picocoulombs per newton. In order to increase the sensitivity of the sensor effect further, multilayer systems consisting of a plurality of foams stacked on one another have been developed.

Gerhard et al. (2007 Annual Report Conference on Electrical Insulation and Dielectric Phenomena, pages 453 to 456) describes a three-layer ferroelectret in which a polytetrafluoroethylene film, which has been provided with a multiplicity of uniform through-holes by mechanical or laser-based drilling, is arranged between two uniform fluoroethylene-propylene films. However, the introduction of through-holes by mechanical or laser-based drilling is elaborate and unsuitable for the production of large batch numbers.

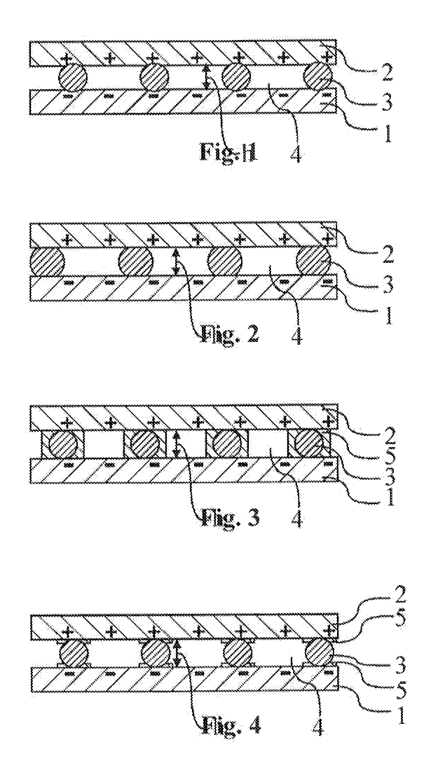

Schwödiauer et al. (2004 IEEE International Ultrasonics, Ferroelectrics, and Frequency Control Joint 50^{th} Anniversary Conference) describes an electret air gap sandwich structure comprising a polypropylene foam between two electrodes, as represented in FIGS. 1 (a) and (b) of this source. Such a structure is produced by a polypropylene foam, which contains particles, being stretched in two spatial directions so as to form cavities. This can be seen in FIG. 1 (b), the bright regions showing the polypropylene framework and the dark regions the flattened cavities. The unordered structure of the hollow polypropylene framework, and the cavities lying in between, can be seen clearly. The thickness and the shape of the “webs” of the polymer framework and the size, the diameter, the height and the shape of the cavities can also be seen to vary, i.e. the size distribution both of the “webs” and of the cavities is large. The variation of the height, i.e. the diameter of the cavities perpendicularly to the electrodes, is particularly critical in this case since it leads to a local variation of the piezoelectric properties, for example the piezoelectric constant and its frequency dependence. In particular, the position of the resonant frequency and the width of the resonant peak of the piezoelectric constant are highly sensitive to a variation in the aforementioned parameters. In particular, the unordered structure of the polypropylene framework and the cavities lying in between leads to nonuniform mechanical properties of the polypropylene foam. A disadvantage of such an arrangement is thus that the electrical and mechanical properties can be adapted only approximately.

It would be desirable to provide a method for producing an electromechanical, for example piezoelectric, transducer, which is suitable for the production of large batch numbers. This method should furthermore make it possible for the electrical and mechanical properties of the transducer to be adjustable. To this end, it should be possible to produce structures in a defined way according to size and position and with the smallest possible size distribution.

The invention therefore provides a method for producing an electromechanical transducer, comprising the steps of:
A) applying a monolayer of spacer elements onto a first polymer layer, the spacer elements having essentially the same height,
B) applying a second polymer layer onto the spacer elements of the monolayer so that there is at least one cavity between the first polymer layer and the second polymer layer, and
C) fixing the spacer elements between the first and second polymer layers.

The term “monolayer” in the context of the invention is intended to mean a single layer of the spacer elements. “Essentially the same height” in the context of the invention is intended to mean that the spacer elements have the same height within the scope of the production tolerance, ter example of less than 5%, in particular less than 1%.

By virtue of the method according to the invention, electromechanical transducers can advantageously be produced in large batch numbers.

The monolayer of spacer elements can advantageously make the electromechanical transducer to be produced softer along its thickness, so as to reduce its modulus of elasticity, permit a poling process in the resulting cavities and/or separate charge layers formed in the polymer layers after the charging process.

A “spacer element” may in particular be interpreted as meaning an element which has a defined shape before introduction into the method. The shape is preferably maintained until the end of the method. The spacer elements may, for example, have a spherolytic or elongate shape. In particular, the spacer elements may be configured spherically or in rod form (filament form). The distance between the polymer films can advantageously be determined by the size of the spacer elements. The density of the spacer elements (number of spacer elements per unit area) and the distribution of the spacer elements (average (maximum) separation of the spacer elements) can be selected suitably according to the mechanical properties of the polymer layers.

The cavity or cavities are, in particular, arranged continuously between the first and second polymer layers. For example the cavity makes contact, or the cavities make contact, on one side with the first polymer layer and on the other side with the second polymer layer. This has an advantageous effect on the electromechanical behaviour of the electromechanical energy transducer to be produced.

In one embodiment of the method, the spacer elements are configured in the form of spheres, in particular solid or hollow spheres, and/or rods, in particular solid or hollow rods (tubes). The spacer elements preferably have a size distribution which is as small as possible. In particular, the spacer elements of the monolayer may have not only essentially the same height, but also essentially an equally large diameter. In this case, “essentially an equally large diameter” may be interpreted as meaning that the spacer elements have the same diameter within the scope of the production tolerance, for example of less than 5%, in particular less than 1%. In this way, it is possible to ensure that the first and second polymer films can be arranged equidistantly. The size, in particular the height and/or diameter, of the spacer elements will preferably be adjusted so that the polymer layers cannot touch and/or the total cavity volume resulting after manufacture is as large as possible. For example, the spacer elements may have a height of from ≧1 μm to ≦800 μm, preferably from ≧10 μm to ≦300 μm, especially preferably from ≧20 μm to ≦200 μm, more especially preferably from ≧50 μm to ≦100 μm and/or a diameter of from ≧1 μm to ≦800 μm, preferably from ≧10 μm to ≦300 μm, especially preferably from ≧20 μm to ≦200 μm, more especially preferably from ≧50 μm to ≦100 μm. The spacer elements are preferably made of an electrically nonconductive and/or electrically nonpolarisable material.

The spacer elements may be applied so as to be distributed either homogeneously or heterogeneously on the first polymer layer. In particular, the spacer elements may be applied so as to be distributed homogeneously on the first polymer layer. Depending on the field of application of the electromechanical transducer to be produced, however, it may also be advantageous to apply the spacer elements so as to be distributed heterogeneously in a spatially resolved way, particularly in a controlled fashion.

The spacer elements may furthermore be configured in different forms. In particular, a multiplicity of spacer elements configured in a first form and a multiplicity of spacer elements configured in a second form, and optionally a multiplicity of spacer elements configured in a third form, etc., may be applied. The spacer elements, configured in different forms, may in this case be applied so as to be distributed either homogeneously or heterogeneously on the first polymer layer. In particular, the electromechanical, in particular piezoelectric, properties of the electromechanical transducer produced by the method according to the invention may be adapted through selection of the spacer element form, spacer element arrangement and/or spacer element distribution.

The spacer elements may in principle be made independently of one another from any material which is suitable for permitting a poling process in the cavities and separating the charge layers formed in the polymer layers after the charging process.

In another embodiment of the method, the spacer elements are made of glass or a polymer. For example, the spacer elements may be made of a mineral glass, in particular silica glass or quartz glass. Polymers for making spacer elements may be selected in almost any desired way. Thermoplastics such as polycarbonates and polystyrenes, in particular polycarbonates, and thermoplastic elastomers such as thermoplastic polyurethanes (TPU), may be mentioned by way of example. For example, the company Liquid Crystal Technologies (LCT) (Cleveland, Ohio, USA) markets suitable polymeric spacer elements. In particular, the spacer elements may be configured in the form of glass spheres and/or polymer spheres and/or glass rods and/or polymer rods.

In another embodiment of the method, the spacer elements are configured in rod form and are applied in a meandering fashion onto the first polymer layer. In this way, rod-shaped, for example flexible spacer elements can be arranged while avoiding rods overlapping one another.

During application of the spacer elements, the spacer elements may be distributed, for example spread.

In another embodiment of the method, the application of the spacer elements onto the first polymer layer in method step A) is carried out by a scattering method and/or a spray method and/or a fluidised bed method and/or a placement method (in particular a placement technique, for example with an automatic placement machine) and/or a priming method and/or a coating method.

In another embodiment of the method, the application of the spacer elements onto the first polymer layer in method step A) is carried out by a printing and/or coating method, a printing and/or coating material which comprises the spacer elements as fillers being used, for example a printing ink, an ink, a paste, a formulation, a lacquer or an adhesive.

After application of the monolayer of spacer elements onto the first polymer layer in method step A), the printing and/or coating material may be partially or fully consolidated, for example dried and/or crosslinked and/or solidified and/or crystallised. This may for example be done thermally, by exposure to ultraviolet light, by exposure to infrared light and/or by drying. If, however, the structure contains polymers with a low UV stability such as polycarbonates, then consolidation is preferably carried out thermally, by exposure to infrared, light and/or by drying. By initially partial and subsequently full consolidation, on the one hand the shape stability of the printed structures can be improved. On the other hand, this offers the possibility of fixing the spacer elements between the first and second polymer layers, or connecting the monolayer of spacer elements both to the first polymer layer and to the second polymer layer, by subsequent, in particular full consolidation.

Method step C) may be carried out either after method steps A) and B) or during and/or before method steps A) and/or B).

For example, in another embodiment of the method, the fixing of the spacer elements is carried out by only partial consolidation, for example drying and/or crosslinking and/or solidification and/or crystallisation, of the printing and/or coating material comprising the spacer elements, after application of the monolayer of spacer elements in method step A) and full consolidation, for example drying and/or crosslinking and/or solidification and/or crystallisation, of the printing and/or coating material comprising the spacer elements, after application of the second polymer layer in method step B).

In another embodiment of the method, the fixing of the spacer elements is carried out by an adhesive bonding method, a layer of adhesive being applied onto the spacer elements and/or the first polymer layer and/or the second polymer layer in method step 0) before method step A), in particular by applying a printing and/or coating material by a printing and/or coating method. In this case, the fixing per se may be carried out during and/or after method step A) and/or during and/or after method step B). In this context and in connection with the lamination method explained below, before method step A) the method may also comprise method step 0): applying a layer of adhesive and/or a thermoplastic layer onto the spacer elements and/or the first polymer layer and/or the second polymer layer, in particular by a printing and/or coating method.

In another embodiment of the method, the fixing of the spacer elements is carried out by a lamination method, in particular at elevated pressure and/or at an elevated temperature and/or with exposure to ultraviolet light and/or exposure to infrared light, a thermoplastic layer being applied onto the spacer elements and/or the first polymer layer and/or the second polymer layer in method step 0) before method step A), in particular by applying a printing and/or coating material by a printing and/or coating method, and/or the spacer elements and/or the first polymer layer and/or the second polymer layer being made of a thermoplastic material. The lamination at elevated pressure and/or at an elevated temperature may, for example, be carried out between two hot rotating cylinders. The pressure and the temperature will in this case preferably be selected so that the polymer layers and spacer elements bind, with the shape of the spacer elements at least essentially being preserved. In the scope of the lamination method, the spacer elements and/or the first polymer layer and/or the second polymer layer and/or the thermoplastic layer/s may be heated.

The method may furthermore comprise method step C1): applying a seal which delimits and seals on the remaining sides the space which is spanned by the spacer elements and delimited on two sides by the polymer layers.

In another embodiment of the method, the fixing of the spacer elements is carried out by a clamping method, the first polymer layer and the second polymer layer being clamped together by one or more clamps. The clamp or clamps may simultaneously be configured as a seal. When fixing by a clamping method, the spacer elements may optionally be pressed to a small extent into the first polymer layer and/or the second polymer layer, the first polymer layer and/or the second polymer layer being slightly deformed and the spacer elements fixed in the respective position. As an alternative or in addition to this, the spacer elements themselves may be slightly deformed and thereby fixed between the first polymer layer and the second polymer layer.

The layer of adhesive may be partially consolidated, for example dried and/or crosslinked and/or solidified and/or crystallised, after application in method step 0). This may be done thermally, by exposure to ultraviolet light, by exposure to infrared light and/or by drying. Preferably, however, the layer of adhesive is consolidated only to such an extent that the adhesive properties are preserved and the spacer elements can adhere to it. After application of the monolayer of spacer elements, particularly in method step A), the layer of adhesive may be hilly consolidated, for example dried and/or crosslinked and/or solidified and/or crystallised, so as to fix the spacer elements.

The thermoplastic layer may be fully consolidated, for example dried and/or crosslinked and/or solidified and/or crystallised, after application in method step 0). This may likewise be done thermally, by exposure to ultraviolet light, by exposure to infrared light and/or by drying.

In another embodiment of the method, the layer of adhesive and/or the thermoplastic layer is a structured layer. The layer of adhesive and/or the thermoplastic layer are therefore preferably made of a material which can be applied onto the polymer layer in defined structures. Structuring of the layer of adhesive and/or the thermoplastic layer may, for example, be configured so that only those regions of the first polymer layer on which spacer elements are subsequently applied are partially or fully coated with the layer of adhesive or the thermoplastic layer. In this way, the regions of the first polymer layer which delimit the resulting cavity are uncoated, which can have an advantageous effect on the piezoelectric properties of the electromechanical transducer being produced.

For example, the spacer methods may be applied in the subsequent method step A), for example by a placement method, only onto the regions of the first polymer layer which have the layer of adhesive or the thermoplastic layer.

The spacer elements may however also be applied in the subsequent method step A) both onto the regions of the first polymer layer which have the layer of adhesive or the thermoplastic layer and onto the regions of the first polymer layer which do not have a layer of adhesive, or do not have a thermoplastic layer.

In another embodiment of the invention, after method step A), the method comprises method step A1): removing spacer elements which do not adhere to the layer of adhesive and/or the thermoplastic layer. This may for example be done by a shaking method, in particular with the polymer layer side having the spacer elements facing downwards, and/or with the aid of an air flow.

For example, the spacer elements may be applied onto a layer of adhesive and/or thermoplastic layer by spraying, scattering or by fluidisation. On the regions of the first polymer layer which are provided with the layer of adhesive, the spacer elements do not however adhere to untreated regions. The spacer elements not adhering on the layer of adhesive can be removed by shaking or tapping. After application of the spacer elements, the layer of adhesive may be crosslinked and/or dried, in particular fully crosslinked and/or dried, for example in order to permanently fix the spacer elements which have been applied.

The application of the layer of adhesive and/or the thermoplastic layer may likewise be carried out by a printing and/or coating method, in particular with a printing and/or coating material, for example a printing ink, an ink, a paste, a formulation, a lacquer or an adhesive.

In the scope of the present invention, for example doctor blading, spin coating, dip coating, spray coating, curtain coating, slot-dye coating, flexographic printing, gravure printing, pad printing, digital printing, thermal transfer printing, relief printing, in particular letterpress printing, planographic printing, intaglio printing (offset printing) and/or screen printing, and/or a roller application method, for example with roller application mechanisms for hot-melt adhesives from the company Hardo Maschinenbau GmbH (Bad Salzuflen, Germany) are suitable as printing and/or coating methods, preferably screen printing. In particular, a structured layer may be applied by doctor blading, spin coating, dip coating, spray coating and/or curtain coating in combination with dies, masks or templates, the templates covering the corresponding polymer layer in particular at the positions which are not intended to be coated. As coating methods without dies, masks or templates, coating by means of slot-dye coating, flexographic printing, gravure printing, pad printing, digital printing, thermal transfer printing, relief printing, in particular letterpress printing, planographic printing, intaglio printing (offset printing) and/or screen printing, and/or a roller application method, preferably a screen printing method, may in particular be used.

The printing and/or coating material, for example the printing ink, the ink, the paste, the formulation, the lacquer or the adhesive, may be formulated directly before processing or commercially available.

For example, the printing and/or coating material may comprise or be made of at least one polymer selected from the group consisting of cellulose esters, cellulose ethers, rubber derivatives, polyester resins, unsaturated polyesters, alkyd resins, phenolic resins, amino resins, amido resins, ketone resins, xylene-formaldehyde resins, epoxy resins, phenoxy resins, polyolefins, polyvinyl chloride, polyvinyl esters, polyvinyl alcohols, polyvinyl acetals, polyvinyl ethers, polyacrylates, polymethacrylates, polystyrenes, polycarbonates, polyesters, copolyesters, polyamides, silicone resins, polyurethanes, in particular polyurethanes and blends of these polymers, in particular as a binder. If the printing and/or coating material comprises a resin, the printing and/or coating material may optionally furthermore contain one or more resin curers. The printing and/or coating material may furthermore contain solvents, additives and other fillers. As additives, for example, thickeners, rheology additives, adhesion promoters, antifoaming agents, deaerators and/or flow control agents may be added to the printing and/or coating material.

Many commercially available products, in particular as a binder, may be suitable as the printing and/or coating material, which are marketed for example under the commercial names Noriphan HTR, Noriphan PCI, Noriphan N2K, Noricryl and NoriPET by the company Pröll KG, Weiβenburg in Bavaria, Germany, or under the commercial name Maraflex FX by the company Marabu GmbH & Co. KG, Tamm, Germany, or under the commercial name Polyplast PY by the company Fujiflim Sericol Germany GmbH, Bottrop, Germany, or under the screen printing ink commercial names HG, SG, CP, CX, PK, J, TL and YN by the company Coates Screen inks GmbH, Nuremberg, Germany, or under the commercial names 1500 Series UV Flexiform, 1600 Power Print Series, 1700 Versa Print, 3200 Series, 1800 Power Print plus, 9700 Series, PP Series, 7200 Lacquer and 7900 Series by the company Nazdar, Shawnee, USA.

As binders for a printing and/or coating material, which cures under ultraviolet light, for example epoxy, ester, ether and/or urethane acrylates are suitable. Urethane acrylates can be used as solutions in reactive diluents (low-viscosity meth/acrylates), as low-viscosity oligomers, as solids for powder coating technology or as urethane acrylate dispersions. Urethane acrylates are available, for example, under the commercial/brand name Desmolux from the company Bayer MaterialScience AG (Leverkusen, Germany). For curing, for example electron beam curing, mono cure technology and dual cure technology are suitable. For dual cure technology, isocyanato-urethane acrylates are particularly suitable.

The printing and/or coating material may be made on the basis of water or on the basis of solvents other than water.

The printing and/or coating material may in particular comprise or be made of one or more polyurethanes. In particular, the printing and/or coating material may comprise or be made of one or more single-component polyurethanes and/or one or more two-component polyurethanes and/or one or more aqueous polyurethane dispersions and/or one or more polyurethane hot-melt adhesives.

For example, the printing and/or coating material may comprise or consist of one or more single-component polyurethanes, which comprise prepolymers producible by reacting alcohols with a stoichiometric excess of polyfunctional isocyanates having an average functionality of more than 2 and up to 4. These prepolymers may optionally furthermore comprise additives and/or solvents.

The prepolymers may, for example, be obtained by reacting polyisocyanates with alcohols, which are mixtures of polyols with on average monofunctional alcohols, to form urethane groups and terminal isocyanate groups.

The polyols known to the person skilled in the art, which are conventional in polyurethane chemistry, may be used as polyols, for example polyether, polyacrylate, polycarbonate, polycaprolactone, polyurethane und polyester polyols, as are described for example in Ullmanns Enzyklopädie der technischen Chemie [Ullmanns Encyclopaedia of Industrial Chemistry], 4^{th} edition, volume 19, pp. 304-5, Verlag Chemie, Weinheim, or in Polyurethan Lacke, Kleb-und Dichtstoffe [Polyurethane coatings, adhesives and sealants] by Ulrich Meier-Westhues, Vincentz Network, Hannover, 2007. For example, the polyols known as Desmophen® from the company Bayer MaterialScience AG, Leverkusen, Germany, may be used.

As polyfunctional isocyanates with an average functionality >2, the products known to the person skilled in the art which are conventional in polyurethane chemistry may be used, as described for example in Ullmanns Enzyklopädie der technischen Chemie, 4^{th} edition, volume 19, pp. 303-4, Verlag Chemie, Weinheim. Examples which may be mentioned are isocyanates trimerised by means of biuret groups, for instance the trimerised hexamethylene diisocyanate Desmodur® N (commercial name of the company Bayer MaterialScience AG, Leverkusen, Germany) or mixtures thereof with diisocyanates, or isocyanates trimerised by means of isocyanurate groups or mixtures thereof with diisocyanates. Adducts of diisocyanates on polyols, for example toluylene diisocyanate on trimethylol propane are also suitable.

Additives such as catalysts to accelerate curing, for example tertiary amines such as dimorpholino diethyl ether, Bis-[2-N,N-(dimethylamino)ethyl]ether or tin compounds, such as dibutyl tin dilaurate or tin-II octoate, antiageing and photoprotective agents, drying agents, stabilisers, for example benzoyl chloride, adhesion promoters to improve adhesion, plasticisers, for example dioctyl phthalate, as well as pigments and fillers may be added to the prepolymers.

Owing to the moisture sensitivity of isocyanates, operation should generally be carried out with careful exclusion of water, that is to say water-free raw materials should be used and ingress of moisture during the reaction should be avoided.

The production of the prepolymers may be carried out by reacting the mixture of polyols and monofunctional alcohol with a stoichiometric excess of di- or polyfunctional isocyanate compound. It is, however, also possible to react the monofunctional hydroxyl compound with the isocyanate compound in a preceding reaction.

The printing and/or coating material may however also comprise or be made of one or more two-component polyurethanes, which comprise for example one component with isocyanate groups and one isocyanate-reactive component.

The NCO compounds known per se to the person skilled in the art, with a functionality of preferably 2 or more, may be used as suitable polyisocyanates for the printing and/or coating material. These are typically aliphatic, cycloaliphatic, araliphatic and/or aromatic di- or triisocyanates and higher molecular weight consecutive products thereof with iminooxadiazindione, isocyanurate, uretdione, urethane, allophanate, biuret, urea, oxadiazintrione, oxazolidinone, acylurea and/or carbodiimide structures, which have two or more free NCO groups.

Examples of such di- or triisocyanates are tetramethylene diisocyanate, cyclohexane-1,3- and 1,4-diisocyanate, hexamethylene diisocyanate (HDI), 1-isocyanato-3,3,5-trimethyl-5-isocyanato-methyl-cyclohexane (isophorone diisocyanate, IPDI), methylene-his-(4-isocyanatocyclohexane), tetramethylxylylene diisocyanate (TMXDI), triisocyanatononane, toluylene diisocyanate (TDI), diphenylmethane-2,4′- and/or -4,4′- and/or -2,2′-diisocyanate (MDI), triphenylmethane-4,4′-diisocyanate, naphtylene-1,5-diisocyanate, 4-isocyanatomethyl-1,8-octane diisocyanate (nonane triisocyanate, triisocyanatononane, TIN) and/or 1,6,11-undecane triisocyanate and any mixtures thereof, and optionally also mixtures of other di-, tri- and/or polyisocyanates. Such polyisocyanates typically have isocyanate contents of from 0.5 percent by weight to 60 percent by weight, preferably from 3 percent by weight to 30 percent by weight, particularly preferably from 5 percent by weight to 25 percent by weight.

Higher molecular weight compounds having isocyanurate, urethane, allophanate, biuret, iminooxadiazintrione, oxadiazintrione and/or uretdione groups based on aliphatic and/or cycloaliphatic and/or aromatic diisocyanates are preferably used in the printing and/or coating material.

Compounds having biuret, iminooxadiazintrione, isocyanurate and/or uretdione groups based on hexamethylene diisocyanate, isophorone diisocyanate, 4,4′-diisocyanatodicyclohexylmethane, diphenylmethane-4,4′-diisocyanate, diphenylmethane-2,4′-diisocyanate, 2,4-toluylene diisocyanate, 2,6-toluylene diisocyanate and/or xylylene diisocyanate are particularly preferably used in the printing and/or coating material.

The production and/or use of the components containing isocyanates may be carried out in a solvent, examples being N-methylpyrrolidone, N-ethylpyrrolidone, xylene, solvent naphtha, toluene, butyl acetate, methoxypropyl acetate, acetone or methyl ethyl ketone. Solvents may be added after reacting the isocyanate groups. In this case, it is also possible to use protic solvents such as alcohols, which for example serve to stabilise the solution or improve coating properties. Any desired mixtures of solvents are also possible. The amount of solvent will generally be dimensioned so as to result in solutions with a strength of from 20 percent by weight to <100 percent by weight, preferably from 50 percent by weight to 90 percent by weight.

In order to accelerate the crosslinking, catalysts may also be added. Suitable catalysts are described in “Polyurethane Chemistry and Technology”, Volume XVI, Part 1, Section IV, pages 129-211, The Kinetics and Catalysis of the Isocyanate Reactions. For example, tertiary amines, tin, zinc or bismuth compounds, or basic salts are suitable. Dibutyl tin dilaurate and octoate are preferred.

Suitable isocyanate-reactive components, for example polyhydroxy compounds, are known per se to the person skilled in the art. These are preferably the binders known per se based on polyhydroxy polyesters, polyhydroxy polyurethanes, polyhydroxy polyethers, polycarbonate diols or on polymers comprising hydroxyl groups, such as the polyhydroxy polyacrylates, polyacrylate polyurethanes and/or polyurethane polyacrylates which are known per se. The polyols known as Desmophen® from the company Bayer MaterialScience AG, Leverkusen, Germany, may be mentioned as examples.

The printing and/or coating material may however also comprise one or more aqueous polyurethane dispersions, for example a polyurethane-polyurea dispersion, or be made of such. Aqueous polyurethane dispersions suitable for a printing and/or coating material for producing an electromechanical transducer according to the invention are those as described for example in U.S. Pat. No. 2,479,310 A, U.S. Pat. No. 4,092,286 A, DE 2 811 148 A, DE 3603996 and EP 08019884.

Diol and/or polyol components suitable for the production of polyurethane-polyurea dispersions are compounds having at least two hydrogen atoms capable of reaction in relation to isocyanates and an average molecular weight of from ≧62 to ≦18000, preferably from ≧62 to ≦4000 g/mol. Examples of suitable structural components are polyether, polyester, polycarbonate, polylactones and polyamides. Preferred polyols have from ≧2 to ≦4 preferably from ≧2 to ≦3 hydroxyl groups. Mixtures of various compounds of this type may also be envisaged.

The polyurethane-polyurea dispersion may be used either separately or in combination with one or more hydrophilically modified crosslinkers. The additional crosslinking of the polyurethane-polyurea polymer leads to a significant increase in the thermal stability and hydrolysis resistance of the adhesive compound.

One or more latent-reactive polyurethane-polyurea dispersions may also be used. Latent-reactive polyurethane-polyurea dispersions are described, for example, in EP 0 922 720 A and WO 2008/071307. The advantage of this product class is that the crosslinking reaction of the polymer can be initiated, for example, by heating in the scope of a laminating process.

The dispersion may be used separately or with the binders, auxiliaries and/or fillers which are known in coating and adhesive technology, in particular emulsifiers and photoprotective agents, such as UV absorbers and sterically hindered amines (HALS), antioxidants, fillers, antisettling agents, antifoaming agents, wetting agents, flow control agents, reactive diluents, plasticisers, neutralisers, catalysts, auxiliary solvents and/or thickeners and/or additives, such as pigments, dyes or matting agents. Tackifiers may also be added. The additives may be added immediately before processing. It is, however, also possible to add at least some of the additives before or during dispersion of the binder.

The choice and dosing of these substances, which may be added to the individual components and/or the overall mixture, are known in principle to the person skilled in the art and can be determined without unreasonably great outlay by simple preliminary tests so as to be tailored to the particular application.

The rheology of the aqueous polyurethane dispersions is preferably adjusted using suitable thickeners so that it no longer flows after application, for example onto the polymer layer. In particular, the structural viscosity of the flow point can in this case be high. The use of such an aqueous polyurethane dispersion has the advantage that the printed layer and/or the coating may initially be dried after application, in which case the polyurethane polymer—depending on the polymer or polymer blend being used—solidifies amorphously and/or crystallises and the printed layer and/or coating can be heated in a subsequent lamination method precisely to such an extent that the polyurethane polymer softens and/or melts and the polymer layer is wetted, the structure of the layer containing the spacers being preserved.

The method may furthermore comprise method step A2): application, in particular congruent application, of at least one further monolayer of spacer elements onto the previous monolayer. Preferably, in this case, a spacer element of the further monolayer is respectively applied on a corresponding spacer element of the previous monolayer, in particular congruently. In this way at least one, in particular continuous, cavity can be formed between the first and second polymer layers. The spacer elements of the further monolayer preferably likewise have essentially the same height, in particular with respect to one another. The fixing of the spacer elements of the further monolayer may be carried out in a similar way as the already explained fixing of the (first) monolayer, in respect of which reference is hereby explicitly made to the disclosure in this context.

The first and/or second polymer layers are preferably compact and/or continuous polymer layers. Here, the term “compact” in the context of the present invention means that the polymer layers have the fewest possible, and in particular no inclusions such as gas bubbles. In particular, the polymer layers are polymer films. The first and/or second polymer layers may in principle be produced independently of one another by all known methods for producing layers and films, in particular thin layers and films. For example, the first and/or second polymer layers may be produced independently of one another by extrusion, doctor blading, in particular solution doctor Wading, spinning, in particular spin coating, or spraying. In the scope of the present invention, it is however also possible to use commercially available polymer layers or polymer films as the first and/or second polymer layers.

In the scope of the present invention, the first and/or second polymer layers may be made independently of one another in principle from any polymer or polymer blend, which is suitable for retaining charge over a prolonged period of time, for example a few months or years. For example, the first and/or second polymer layers may comprise or consist of virtually any identical or different polymer materials. For example, the first and/or second polymer layers may comprise or be made of at least one polymer selected from the group consisting of polycarbonates, perfluorinated or partially fluorinated polymers and copolymers such as polytetrafluoroethylene (PTFE), fluoroethylenepropylene (FEP), perfluoroalkoxyethylenes (PFA), polyesters, such as polyethylene terephthalate (PET) or polyethylene naphthalate (PEN), polyimides, in particular polyether imide, polyethers, polymethyl methacrylates, cyclo-olefin polymers, cyclo-olefin copolymers, polyolefins, such as polypropylene, and blends of these polymers. Such polymers can advantageously retain the applied polarisation for a long time. Suitable polycarbonates may be obtained for example by reacting carboxylic acid derivatives, such as a diphenyl carbonate, dimethyl carbonate or phosgene, with polyols, preferably diols. Examples of suitable diols are ethylene glycol, 1,2-propanediol, 1,3-propanediol, 1,3-butanediol, 1,4-butanediol, 1,6-hexanediol, 1,8-octanediol, neopentyl glycol, 1,4-bishydroxymethyleyelohexane, 2-methyl-1,3-propanediol, 2,2,4-trimethylpentanediol-1,3, dipropylene glycol, polypropylene glycols, dibutylene glycol, polybutylene glycols, bisphenol A, bisphenol F, trimethyl-cyclohexyl-bisphenol (bisphenol-TMC), blends of these and lactone-modified diols. Polycarbonates produced from bisphenol A, bisphenol F, cyclohexyl-bisphenol (bisphenol-TMC) and mixtures thereof are preferred, and polycarbonates based on bisphenol A are particularly preferred. The polymer layers may furthermore independently of one another comprise or be made of a homopolymer.

The first and/or second polymer layers may furthermore comprise at least one additive to improve the electret and/or electromechanical, for example piezoelectric properties. The additive may in this case improve any polymer properties and parameters which have an effect on the electromechanical, for example piezoelectric properties of the material. For example, the additive may improve the electret properties, the dielectric constant, the modulus of elasticity, the viscoelastic behaviour, the maximum extension and/or the dielectric breakdown strength of the polymer or polymer blend. It is preferable to use an additive or a plurality of additives which improve the electret properties, that is to say which increase the charge storage capacity, reduce the electrical conductivity and/or increase the dielectric breakdown strength of the polymer. For example clay particles, fine ceramic powders and/or plasticisers such as hydrocarbon oils, mineral oils, silicone oils and/or silicone elastomers, in particular with a high molecular weight, may be used as additives. Advantageously, several material properties can be improved simultaneously through the selection of a plurality of additives.

In the scope of the present invention, particularly in finished electromechanical transducers, the first and/or second polymer layers may independently of one another have a layer thickness of for example from ≧10 μm to ≦500 μm, preferably from ≧20 μm to ≦250 μm, particularly preferably from ≧50 μm to ≦200 μm, more particularly preferably from ≧100 μm to ≦150 μm.

Optionally, the polymer layers may be heat-treated before use in the method according to the invention or in the scope of the method according to the invention.

The method may furthermore comprise method step D): applying an electrode onto the first polymer layer and an electrode onto the first and/or second polymer layer. In the scope of the present invention, however, the electrodes may already be provided together with the first and/or second polymer layers, and in particular may respectively be formed on them.

The electrodes may be applied by means of methods known to the person skilled in the art. To this end, for example, methods such as physical vapour deposition (PVD), for example sputtering and/or evaporation coating, chemical vapour deposition (CVD), printing, doctor blading and spin coating may be envisaged. The electrodes may also be adhesively bonded in prefabricated form.

The electrode materials may be conductive materials known to the person skilled in the art. To this end, for example, metals, metal alloys, semiconductors, conductive oligo- or polymers such as polythiophenes, polyanilines, polypyrroles, conductive oxides or mixed oxides such as indium tin oxide (ITO), or polymers filled with conductive fillers may be envisaged. As fillers for polymers filled with conductive fillers, for example metals such as silver, aluminium and/or copper, conductive carbon-based materials, for example carbon black, carbon nanotubes (CNTs), graphenes or conductive oligo- or polymers may be envisaged. The filler content of the polymers preferably lies above the percolation threshold, which is characterised in that the conductive fillers form continuous electrically conductive paths.

In the scope of the present invention, the electrodes may also be structured. For example, the electrodes may be structured so that the transducer has active and passive regions. In particular, the electrodes may be structured so that, particularly in sensor mode, the signals can be detected in a spatially resolved fashion and/or, particularly in actuator mode, the active regions can be driven in a controlled fashion. This may, for example, be achieved in providing the active regions with electrodes whereas the passive regions do not have electrodes.

The method may furthermore comprise method step E): charging the arrangement, in particular sandwich arrangement, resulting from method step C). In particular, the first and second polymer layers may be charged with charges of different sign. The charging may for example be carried out by trihocharging, electron beam bombardment, applying an electric voltage to the electrodes or corona discharge. In particular, the charging may be carried out by using a two-electrode corona arrangement. In this case, the needle voltage may be at least ≧20 kV, for example at least ≧25 kV, in particular at least ≧30 kV. The charging time may be at least ≧20 s, for example at least ≧30 s, in particular at least ≧1 min. In the scope of the present invention, method step D) may be carried out first followed by a method step E), or method step E) may be carried out first followed by a method step D).

The method may furthermore comprise method step F): stacking together two or more of the arrangements, in particular sandwich arrangements, resulting from method step C). In this case, the first and second polymer layers may respectively be contacted by an electrode. Preferably, two neighbouring polymer layers of different arrangements resulting from method step C) may be charged with the same polarisation. In particular, two neighbouring polymer layers of different arrangements resulting from method step C) may contact the same electrode or be contacted by the same electrode.

In respect of other features of the method according to the invention, reference is hereby explicitly made to the explanations in connection with the electromechanical transducer according to the invention and its use.

The present invention also relates to an electromechanical, for example piezoelectric transducer, in particular produced by a method according to the invention, which comprises a first polymer layer, a monolayer of spacer elements and a second polymer layer, the monolayer of spacer elements being arranged between the first polymer layer and the second polymer layer, the spacer elements of the monolayer having essentially the same height, and there being at least one cavity between the first polymer layer and the second polymer layer.

The spacer elements may, for example, have a spherolytic or elongate shape. In particular, the spacer elements may be configured spherically or in rod form (filament form). The distance between the polymer films can advantageously be determined by the size of the spacer elements. The density of the spacer elements (number of spacer elements per unit area) and the distribution of the spacer elements (average (maximum) separation of the spacer elements) can be selected suitably according to the mechanical properties of the polymer layers. The cavity or cavities between the first and second polymer layers contact in particular the first polymer layer on one side and the second polymer layer on the other side.

The spacer elements may be configured in the form of spheres, in particular solid or hollow spheres, and/or rods, in particular solid or hollow rods (tubes). The spacer elements preferably have a size distribution which is as small as possible. In particular, the spacer elements of the monolayer may have not only essentially the same height, but also essentially an equally large diameter. In this way, it is possible to ensure that the first and second polymer films can be arranged equidistantly. The size, in particular the height and/or diameter, of the spacer elements will preferably be adjusted so that the polymer layers cannot touch and/or the total cavity volume resulting after manufacture is as large as possible. For example, the spacer elements may have a height of from ≧1 μm to ≦800 μm, preferably from ≧10 μm to ≦300 μm, especially preferably from ≧20 μm to ≦200 μm, more especially preferably from ≧50 μm to ≦100 μm and/or a diameter of from ≧1 μm to ≦800 μm, preferably from ≧10 μm to ≦300 μm, especially preferably from ≧20 μm to ≦200 μm, more especially preferably from ≧50 μm to ≦100 μm. The spacer elements are preferably made of an electrically nonconductive and/or electrically nonpolarisable material.

The spacer elements may be applied so as to be distributed either homogeneously or heterogeneously on the first polymer layer. In particular, the spacer elements may be applied so as to be distributed homogeneously on the first polymer layer. Depending on the field of application of the electromechanical transducer to be produced, however, it may also be advantageous to apply the spacer elements so as to be distributed heterogeneously in a spatially resolved way, particularly in a controlled fashion.

The spacer elements may furthermore be configured in different forms. In particular, a multiplicity of spacer elements configured in a first form and a multiplicity of spacer elements configured in a second form, and optionally a multiplicity of spacer elements configured in a third form, etc., may be applied.

The spacer elements, configured in different forms, may in this case be applied so as to be distributed either homogeneously or heterogeneously on the first polymer layer. On the other hand the electromechanical, in particular piezoelectric, properties of the electromechanical transducer produced by the method according to the invention may be adapted through selection of the spacer element form, spacer element arrangement and/or spacer element distribution.

The spacer elements may in principle be made independently of one another from any material which is suitable for permitting a poling process in the cavities and separating the charge layers formed in the polymer layers after the charging process. In particular, the spacer elements may be made of glass or a polymer. For example, the spacer elements may be made of a mineral glass, in particular silica glass or quartz glass. Polymers for making spacer elements may be selected in almost any desired way. Thermoplastics such as polycarbonates and polystyrenes, in particular polycarbonates, and thermoplastic elastomers such as thermoplastic polyurethanes (TPU), may be mentioned by way of example. For example, the company Liquid Crystal Technologies (LCT) (Cleveland, Ohio, USA) markets suitable polymeric spacer elements. In particular, the spacer elements may be configured in the form of glass spheres and/or polymer spheres and/or glass rods and/or polymer rods.

For example, the spacer elements may be configured in rod form and are applied in a meandering fashion onto the first polymer layer.

Furthermore, the electromechanical transducer may have a seal which delimits and seals on the remaining sides the space which is spanned by the spacer elements and delimited on two sides by the polymer layers.

The electromechanical transducer may furthermore have one or more clamps, which in particular clamp the first and second polymer layers together and thereby fix the spacer elements between the first and second polymer layers. The clamp or clamps may simultaneously be configured as a seal.

The spacer elements may be arranged in a fixing layer, and/or on and/or partially in a fixing layer, so as to form cavities.

For example, such a fixing layer may comprise or be made of at least one polymer selected from the group consisting of cellulose esters, cellulose ethers, rubber derivatives, polyester resins, unsaturated polyesters, alkyd resins, phenolic resins, amino resins, amido resins, ketone resins, xylene-formaldehyde resins, epoxy resins, phenoxy resins, polyolefins, polyvinyl chloride, polyvinyl esters, polyvinyl alcohols, polyvinyl acetals, polyvinyl ethers, polyacrylates, polymethacrylates, polystyrenes, polycarbonates, polyesters, copolyesters, polyamides, silicone resins, polyurethanes, in particular polyurethanes, and blends of these polymers. In particular, such a fixing layer may comprise or be made of one or more single-component polyurethanes and/or one or more two-component polyurethanes and/or one or more aqueous polyurethane dispersions and/or one or more polyurethane hot-melt adhesives.

The first and/or second polymer layers are preferably compact and/or continuous polymer layers. Here, the term “compact” in the context of the present invention means that the polymer layers have the fewest possible, and in particular no inclusions such as gas bubbles. In particular, the polymer layers are polymer films.

The first and/or second polymer layers may, for example, independently of one another have a layer thickness of for example from ≧10 μm to ≦500 μm, preferably from ≧20 μm to ≦250 μm, particularly preferably from ≧50 μm to ≦200 μm, more particularly preferably from ≧100 μm to ≦150 μm.

For example, the first and/or second polymer layers may comprise or be made of at least one polymer selected from the group consisting of polycarbonates, perfluorinated or partially fluorinated polymers and copolymers such as polytetrafluoroethylene (PTFE), fluoroethylenepropylene (FEP), perfluoroalkoxyethylenes (PFA), polyesters, such as polyethylene terephthalate (PET) or polyethylene naphthalate (PEN), polyimides, in particular polyether imide, polyethers, polymethyl methacrylates, cyclo-olefin polymers, cyclo-olefin copolymers, polyolefins, such as polypropylene, and blends of these polymers.

An electromechanical transducer may furthermore have at least one further monolayer of spacer elements which is applied, in particular congruently, on the previous monolayer. Preferably, in this case, a spacer element of the further monolayer is respectively applied on a corresponding spacer element of the previous monolayer, in particular congruently. In this way there can be at least one, in particular continuous, cavity between the first and second polymer layers. The spacer elements of the further monolayer preferably likewise have essentially the same height, in particular with respect to one another. The further monolayers, in particular, are likewise arranged between the first polymer layer and the second polymer layer.

An electromechanical transducer preferably furthermore comprises two electrodes, in particular electrode layers, one electrode contacting the first polymer layer and the other electrode contacting the second polymer layer. The first polymer layer and the second polymer layer may furthermore have an electric charge with a different sign. In particular, an electromechanical transducer according to the invention may comprise two or more arrangements, in particular sandwich arrangements, stacked on one another, each of which comprises a first polymer layer, a monolayer of spacer elements and a second polymer layer, the monolayer of spacer elements being arranged between the first polymer layer and the second polymer layer, the spacer elements of the monolayer essentially having the same height, and there being at least one cavity between the first polymer layer and the second polymer layer. In this case, the first and second polymer layers may respectively contact an electrode. Preferably, two neighbouring polymer layers of different arrangements have the same charge polarisation. In particular, two neighbouring polymer layers of different arrangements may in this case contact the same electrode.

In respect of other features of the electromechanical transducer according to the invention, reference is hereby explicitly made to the explanations in connection with the method according to the invention and the use according to the invention.

The present invention also relates to the use of a transducer according to the invention as a sensor, generator and/or actuator, for example in electromechanical and/or electroacoustic sector, particularly in the field of energy harvesting from mechanical oscillations, acoustics, ultrasound, medical diagnosis, acoustic microscopy, mechanical sensor technology, in particular pressure, force and/or strain sensor technology, robotics and/or communication technology, particularly in loudspeakers, oscillation transducers, light deflectors, diaphragms, modulators for glass fibre optics, pyroelectric detectors, capacitors and control systems.

In respect of other features of the use according to the invention, reference is hereby explicitly made to the explanations in connection with the method according to the invention and the electromechanical transducer according to the invention.

### DRAWINGS AND EXPERIMENTAL DESCRIPTION

The inventive production and structure of an electromechanical, in particular piezoelectric, transducer will be explained in more detail with the aid of the drawings and the following drawing description. It should be remembered that the drawings and the experimental description are only descriptive in nature and are not intended to restrict the invention in any way.

### DRAWINGS

FIG. 1 shows a schematic cross section through a first embodiment of an electromechanical transducer according to the invention, the polymer layers of which are made of a thermoplastic material;

FIG. 2 shows a schematic cross section through a second embodiment of an electromechanical transducer according to the invention, the spacer elements of which are made of a thermoplastic material;

FIG. 3 shows a schematic cross section through a third embodiment of an electromechanical transducer according to the invention, the spacer elements of which have been applied as fillers in a printing material;

FIG. 4 shows a schematic cross section through a fourth embodiment of an electromechanical transducer according to the invention, the spacer elements of which are fixed by means of a structured layer of adhesive or a thermoplastic layer; and

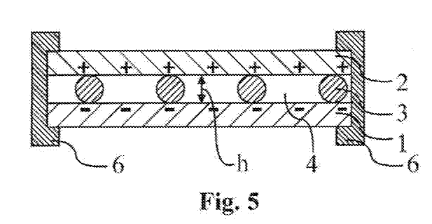

FIG. 5 shows a schematic cross section through a fourth embodiment of an electromechanical transducer according to the invention, the spacer elements of which are fixed by clamping the polymer layers together with clamps.

FIG. 1 shows a schematic cross section through a first embodiment of an electromechanical transducer according to the invention, which comprises a first polymer layer 1, a monolayer of spacer elements 3 and a second polymer layer 2. FIG. 1 shows that the monolayer of spacer elements 3 is arranged between the first polymer layer 1 and the second polymer layer 2, the spacer elements 3 of the monolayer essentially having the same height h. Here, “essentially” means in particular that manufacturing-related height differences are covered. FIG. 1 furthermore shows that there is a cavity 4 between the first polymer layer 1 and the second polymer layer 2.

In the scope of the first embodiment shown for the electromechanical transducer according to the invention, the first 1 and second 2 polymer layers are made of a thermoplastic material. The spacer elements 3 are made of a non-thermoplastic material and have been fixed by a laminating method in which the spacer elements 3 were pressed into the thermoplastic polymer layers 1, 2 at elevated temperature and pressure and the thermoplastic polymer layers 1, 2 were deformed.

FIG. 2 shows a schematic cross section through a second embodiment of an electromechanical transducer according to the invention, which differs from the first embodiment essentially in that instead of the first and second polymer layers 1, 2, the spacer elements 3 are made of a thermoplastic material. FIG. 2 shows that the thermoplastic spacer elements 3 are deformed by a laminating method at elevated temperature and pressure and fixed between the first 1 and second 2 polymer layers.

FIG. 3 shows a schematic cross section through a third embodiment of an electromechanical transducer according to the invention, which differs from the first and second embodiments essentially in that the spacer elements 3 have been applied onto the first polymer layer 1 as fillers in a printing material 5 by a printing method and are present in a fixing layer 5, which is structured so as to form cavities 4 and connects the first 1 and second polymer 2 layers to one another.

FIG. 4 shows a schematic cross section through a fourth embodiment of an electromechanical transducer according to the invention, which differs from the third embodiment essentially in that the spacer elements 3 are fixed on the first 1 and second 2 polymer layers by an adhesive bonding method (or laminating method) by means of structured layers of adhesive (or thermoplastic layers) 5.

FIG. 5 shows a schematic cross section through a fifth embodiment of an electromechanical transducer according to the invention, which differs from the other embodiments essentially in that it has clamps 6 which clamp the polymer layers 1, 2 together and thereby fix the spacer elements 3 between the polymer layers 1, 2, FIG. 5 furthermore shows that the clamps are simultaneously configured as seals, which delimit and seal on the remaining sides the cavity 4 which is spanned by the spacer elements 3 and delimited on two sides by the polymer layers 1, 2.

1. A method for producing an electromechanical transducer, comprising:
A) applying a monolayer of spacer elements onto a first polymer layer, wherein the spacer elements have essentially the same height (h),
B) applying a second polymer layer onto the spacer elements of the monolayer such that at least one cavity is formed between the first polymer layer and the second polymer layer, and
C) fixing the spacer elements between the first and second polymer layers.

2. The method according to claim 1, wherein the spacer elements are configured in the form of one or more of spheres and rods.

3. The method according to claim 1, wherein the spacer elements are configured in rod form and are applied in a meandering fashion onto the first polymer layer.

4. The method according to claim 1, wherein the spacer elements are made of one of glass and a polymer.

5. The method according to claim 1, wherein the spacer elements have a height (h) of from—≧1 μm to ≦800.

6. The method according to claim 1, wherein the application of the spacer elements onto the first polymer layer in step A) comprises one or more selected from the group consisting of a scattering method, a spray method, fluidized bed method, a placement method, a printing method and a coating method.

7. The method according to claim 1, wherein the application of the spacer elements onto the first polymer layer in step A) comprises a printing and/or coating method including a printing and/or coating material and wherein the spacer elements contains fillers.

8. The method according to claim 7, wherein the fixing of the spacer elements comprises partial consolidation of the printing and/or coating material containing the spacer elements after application of the monolayer of spacer elements in step A), and full consolidation of the printing and/or coating material containing the spacer elements after application of the second polymer layer in step B).

9. The method according to claim 1, wherein the fixing of the spacer elements
is carried out by comprises one or more selected from the group consisting of an adhesive bonding method, wherein a layer of adhesive is applied onto the spacer elements and/or the first polymer layer and/or the second polymer layer in a preliminary step 0) prior to method step A) by applying a printing and/or coating material by a printing and/or coating method,
a lamination method,
wherein a thermoplastic layer is applied onto the spacer elements and/or the first polymer layer and/or the second polymer layer in a preliminary step 0) prior to step A) by applying a printing and/or coating material by a printing and/or coating method, and wherein one or more of the spacer elements, the first polymer layer and the second polymer layer are made of a thermoplastic material, and
by a clamping method, wherein the first polymer layer and the second polymer layer are clamped together by a clamp.

10. The method according to claim 7, wherein the printing and/or coating material comprises at least one polymer selected from the group consisting of cellulose esters, cellulose ethers, rubber derivatives, polyester resins, unsaturated polyesters, alkyd resins, phenolic resins, amino resins, amido resins, ketone resins, xylene-formaldehyde resins, epoxy resins, phenoxy resins, polyolefins, polyvinyl chloride, polyvinyl esters, polyvinyl alcohols, polyvinyl acetals, polyvinyl ethers, polyacrylates, polymethacrylates, polystyrenes, polycarbonates, polyesters, copolyesters, polyamides, silicone resins, polyurethanes and blends of these polymers.

11. The method according to claim 7, wherein the printing and/or coating material comprises one or more selected from the group consisting of single-component polyurethanes, two-component polyurethanes, aqueous polyurethane dispersions and polyurethane hot-melt adhesives.

12. The method according to claim 9, wherein the layer of adhesive and/or the thermoplastic layer is a structured layer.

13. The method according to claim 9, wherein further including step A1) following step A), wherein step A1) comprises
removing spacer elements which do not adhere to the layer of adhesive and/or the thermoplastic layer.

14. An electromechanical transducer, comprising
a first polymer layer,
a monolayer of spacer elements, and
a second polymer layer,
wherein the monolayer of spacer elements are arranged between the first polymer layer and the second polymer layer, of the monolayer have essentially the same height (h), and
there is at least one cavity between the first polymer layer and the second polymer layer.

15. The method according to claim 1, wherein the spacer elements have a diameter of from ≧1 μm to ≦800 μm.
